(19) United States
(12) Patent Application Publication
(10) Pub. No.: US 2026/0136489 A1
(43) Pub. Date: May 14, 2026

(54) IMMERSION COOLING APPARATUS AND CONDENSER MODULE OF THE SAME

(71) Applicant: Wiwynn Corporation, New Taipei City (TW)

(72) Inventors: HSIEN-CHIEH HSIEH, New Taipei City (TW); Fu Sheng Cheng, New Taipei City (TW); Tsung-Han Li, New Taipei City (TW)

(21) Appl. No.: 19/207,483

(22) Filed: May 14, 2025

Related U.S. Application Data
(60) Provisional application No. 63/717,960, filed on Nov. 8, 2024.

(30) Foreign Application Priority Data
Feb. 24, 2025 (TW) 114106716

(51) Int. Cl. H05K 7/20

(52) U.S. Cl. CPC H05K 7/20236

(57) ABSTRACT

A condenser module of an immersion cooling apparatus includes a sealing plate, an inlet water box, an outlet water box, a connection water box, a plurality of first pipes and a plurality of second pipes. The sealing plate is configured to seal a tank of the immersion cooling apparatus. The inlet water box is fixed to the sealing plate. The outlet water box is fixed to the sealing plate. The first pipes are connected between the inlet water box and the connection water box. The second pipes are connected between the outlet water box and the connection water box.

This application claims priority under 35 U.S.C. § 119(e) on U.S. Provisional Application No. 63/717,960 filed on Nov. 8, 2024, and under 35 U.S.C. § 119(a) on Patent Application No. 114106716 filed in Taiwan, R.O.C. on Feb. 24, 2025, the entire contents of which are hereby incorporated by reference.

### BACKGROUND

### 1. Technical Field

The present disclosure is related to an immersion cooling apparatus and a condenser module.

### 2. Related Art

Currently, the condenser in an immersion cooling apparatus is fixed inside of the tank by welding. When the condenser requires maintenance, it cannot be removed from the tank and therefore should be maintained in situ, which causes the maintenance process inconvenience and reduces efficiency. Accordingly, those skilled in this art are working hard to solve the above problems.

### SUMMARY

It is therefore an objective of the present disclosure to provide an immersion cooling apparatus and a condenser module for facilitating maintenance operation and efficiency.

According to one embodiment of the present disclosure, a condenser module of an immersion cooling apparatus includes a sealing plate, an inlet water box, an outlet water box, a connection water box, a plurality of first pipes and a plurality of second pipes. The sealing plate is configured to seal a tank of the immersion cooling apparatus. The inlet water box is fixed to the sealing plate. The outlet water box is fixed to the sealing plate. The first pipes are connected between the inlet water box and the connection water box. The second pipes are connected between the outlet water box and the connection water box.

According to another embodiment of the present disclosure, an immersion cooling apparatus includes a tank and the aforementioned condenser module. The tank includes a lateral wall having a window. The condenser module is disposed in the tank through the window, and the sealing plate of the condenser module is configured to seal the window.

The immersion cooling apparatus and the condenser module have the following advantages: (1) the sealing plate is integrated with the condenser module to seal the tank, thereby making installation and removal convenient; (2) the condenser module can be removed from the tank, thereby making maintenance and cleaning convenient; (3) the inlet and outlet joints are disposed on the sealing plate and located outside of the tank, thereby reducing the risk of damage to the electronic devices due to conductive coolant leakage; (4) a conveyor is disposed below the condenser module, thereby making installation and removal convenient; and (5) a coolant slide is disposed below the condenser module to direct coolant to heat-generating electronic devices, thereby improving cooling efficiency.

### BRIEF DESCRIPTION OF THE DRAWINGS

FIG. 1 is a perspective view of an immersion cooling apparatus according to one embodiment of the present disclosure;

FIG. 2 is a perspective view of parts of the tank, the conveyor module and the coolant slide in FIG. 1;

FIG. 3 is a top view of the tank, the conveyor module and the coolant slide in FIG. 2;

FIG. 4 is a perspective view of the condenser module in FIG. 1;

FIG. 5 is a side view of the immersion cooling apparatus with the condenser module removed therefrom;

FIG. 6 is a side view of the immersion cooling apparatus with the condenser module disposed therein.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present disclosure. The following embodiments further illustrate various aspects of the present disclosure, but are not meant to limit the scope of the present disclosure.

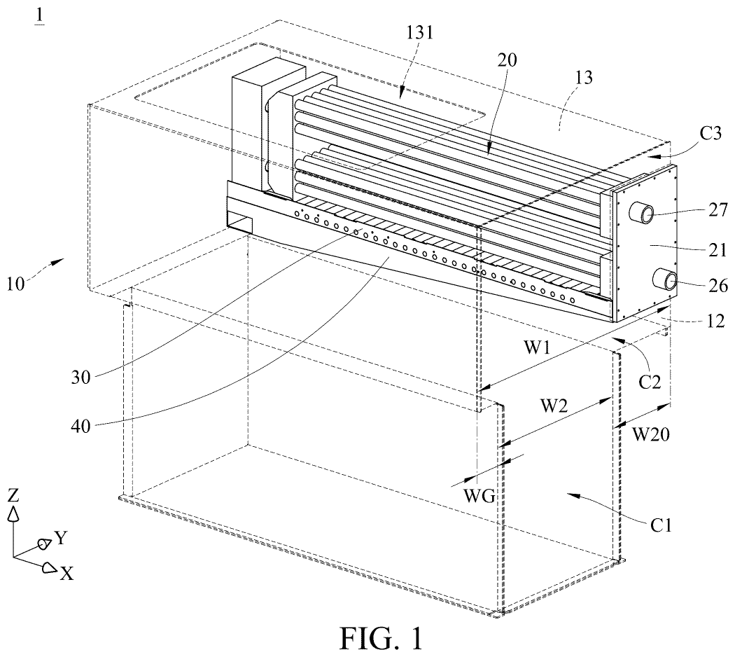

FIG. 1 is a perspective view of an immersion cooling apparatus 1 according to one embodiment of the present disclosure. The immersion cooling apparatus 1 includes a tank 10 and a condenser module 20. A non-conductive liquid coolant (not shown in the drawings) can be injected into the tank 10. After absorbing heat generated by electronic devices, the coolant evaporates into coolant vapor. Since the coolant does not completely fill the tank 10, the tank 10 contains air.

It should be understood that since gravity is proportional to mass, the substance with greater mass or density will move to the bottom of the tank 10 due to gravity, while the substance with less mass or density will move to the top of the tank 10 due to buoyancy and the reaction force of any moving substance. Furthermore, since the liquid coolant has a greater density than that of the coolant vapor and the coolant vapor has a greater molecular weight than those of air and water vapor, a liquid region C1, a vapor region C2 and an air region C3 are naturally formed in the tank 10. The liquid region C1 has the lowest altitude, the air region C3 has the highest altitude, and the vapor region C2 is between the liquid region C1 and the air region C3. Thus, the condenser module 30 is disposed in the vapor region C2 to condense vapor.

In one embodiment, an opening 131 is formed on the top surface 13 of the tank 10, parallel to the X-Y plane. The electronic devices (not shown in the drawings) can be placed in the tank 10 or removed from the same through the opening 131. In one embodiment, the opening 131 may be sealed by a lid (not shown in the drawings).

In one embodiment, the condenser module 20 includes a sealing plate 21, an inlet joint 26 and an outlet joint 27. The sealing plate 21 is located outside of the tank 10 for sealing. The inlet joint 26 as well as the outlet joint 27 are disposed on the sealing plate 21 and located outside of the tank 10. It should be understood that conductive coolant (e.g. water) is in the condenser module 20, and the inlet joint 26 and the outlet joint 27 are connection interfaces with lower structural strength. Locating the inlet joint 26 and the outlet joint 27 on the sealing plate 21 and outside of the tank 10, it can reduce the risk of damage to the electronic devices due to conductive coolant leakage.

In one embodiment, the immersion cooling apparatus 1 further includes a conveyor module 30 disposed in the vapor region C2 of the tank 10 and located below the condenser module 20. The conveyor module 30 is configured to transport the condenser module 20 inside of the tank 10. Moreover, the conveyor module 30 is an optional module, and it may be omitted in other embodiments.

In one embodiment, the immersion cooling apparatus 1 further includes a coolant slide 40 disposed below the condenser module 20 and above the liquid region C1. The coolant slide 40 is configured to collect and direct condensed coolant over heat-generating electronic devices, thereby improving cooling efficiency. In one embodiment, one or more ribs (not shown in the drawings) may be disposed below the coolant slide 40 to support the coolant slide 40. Moreover, the coolant slide 40 is an optional module, and it may be omitted in other embodiments.

In one embodiment, in the Y-axis direction, the width W1 of the vapor region C2 is greater than the width W2 of the liquid region C1. In detail, the dimension of the liquid region C1 is determined based on the dimension of the electronic devices, such that the width W2 of the liquid region C1 should be greater than that of the electronic devices in the Y-axis direction. The dimension of the vapor region C2 is determined based on the dimensions of the electronic devices and the condenser module 20, such that the width W1 of the vapor region C2 is equal to the sum of a reserved width WG, the width W2 of the liquid region C1 as well as the width W20 of the condenser module 20 in the Y-axis direction; that is, W1=WG+W2+W20. As can be seen from FIG. 1, the projection of the tank 10 onto the Y-Z plane is T-shaped. An upper portion of the tank 10 is wider to prevent the condenser module 20 from interfering with the electronic devices when they are entering and exiting the tank 10, and a lower portion of the tank 10 is narrower to minimize coolant usage.

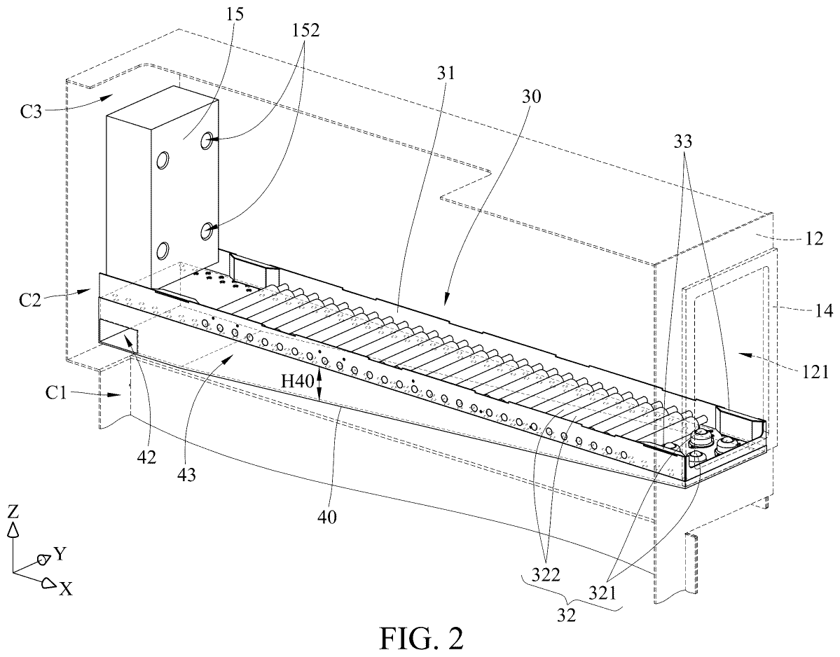

FIG. 2 is a perspective view of parts of the tank, the conveyor module and the coolant slide in FIG. 1. A lateral wall 12 (parallel to the Y-Z plane) of the tank 10 is formed with a window 121. The condenser module 20 (shown in FIG. 1) can be loaded into or drawn out from the tank 10 through the window 121. Therefore, when the condenser module 20 needs to be maintained or cleaned, a ready condenser module can be put into the tank 10 through the window 121 for replacement. Thus, the downtime for electronic device can be shortened and maintenance and cleaning of the condenser module 20 outside of the tank 10 can be proceeded with ease. In other embodiments, multiple condenser modules may be disposed in the tank 10, and they can be put into the tank 10 through the same lateral wall 12 or different lateral walls.

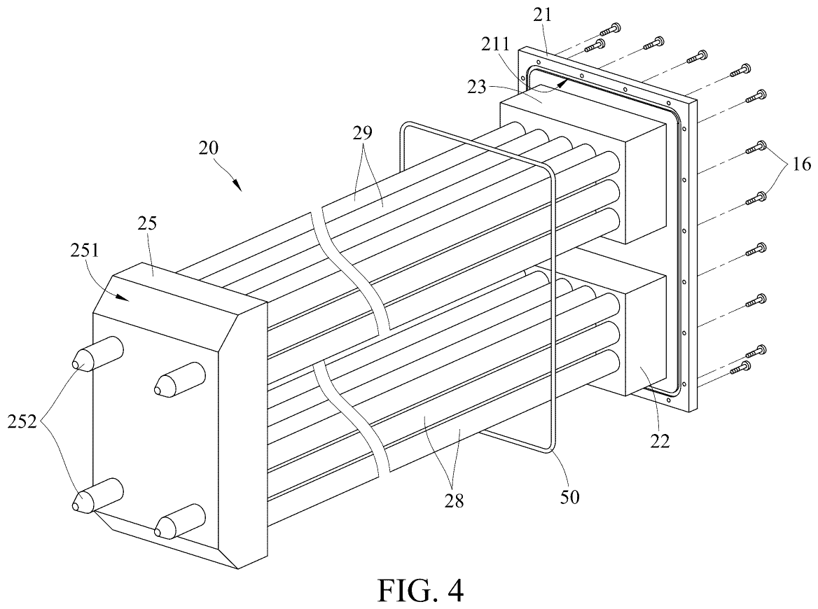

In one embodiment, the immersion cooling apparatus 1 further includes a frame 14 fixed to an outer surface of the lateral wall 12 and surrounding the window 121. A plurality of blind holes (not shown in the drawings) may be formed on the frame 14, a plurality of through holes (shown in FIG. 1) may be formed on the sealing plate 21, and a plurality of screws 16 (shown in FIG. 4) may pass through the through holes and are screwed into the blind holes, thereby enhancing the sealing performance between the tank 10 and the sealing plate 21.

In one embodiment, the immersion cooling apparatus 1 further includes a mounting base 15 disposed on another lateral wall opposite to the lateral wall 12 and located in the vapor region C2. The mounting base 15 is configured to fix the condenser module 20. The mounting base 15 has a plurality of first guiding structures 152. When a plurality second guiding structures 252 (shown in FIG. 4) of the condenser module 20 engage with the first guiding structures 152, the condenser module 20 is fixed to the mounting base 15.

In one embodiment, the conveyor module 30 includes a tray 31 and a plurality of rotating elements 32. The rotating elements 32 are disposed on the tray 31. In one embodiment, the rotating elements 32 includes at least one universal ball 321 and at least one roller 322. In the embodiment of FIG. 2, the at least one universal ball 321 is proximate to the window 121, and the at least one roller 322 is not proximate to the window 121. Since the moving direction of the condenser module 20 is unstable when it is entering to the tank 10 through the window 121, and the universal ball 321 can adapt to such directional variations. On the other hand, once a part of the condenser module 20 entered the tank 10, the moving direction of the condenser module 20 becomes more stable, allowing the roller 322 to adapt to such stable movement. However, in other embodiments, the rotating elements 32 may be all universal balls or rollers. Furthermore, the rotating element 32 is an optional element, and it may be omitted or replaced by any other suitable element in other embodiments.

In one embodiment, the conveyor module 30 further includes a plurality of guiding elements 33 respectively disposed at opposite lateral walls of the tray 31 for directing the condenser module 20. The guiding element 33 may be a trapezoidal column, a semi-cylinder and the like, but the present disclosure is not limited thereto. Moreover, the guiding element 33 is an optional element, and it may be omitted or replaced by any other suitable element in other embodiments.

In one embodiment, an exit 42 is formed on a lateral surface 43 (parallel to the X-Z plane) of the coolant slide 40, and the exit 42 is located at a side of the coolant slide 40 away from the window 121 and below the mounting base 15. In one embodiment, the height H40 of the lateral surface 43 of the coolant slide 40 in the Z-axis direction gradually increases from the window 121 toward the exit 42, thereby directing the liquid coolant to the exit 42.

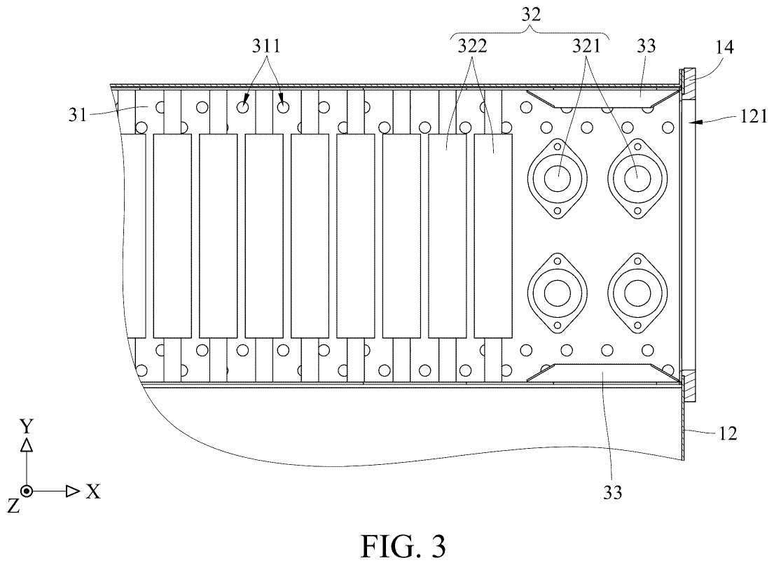

FIG. 3 is a top view of the tank, the conveyor module 30 and the coolant slide 40 in FIG. 2. In one embodiment, the tray 31 is formed with a plurality of drain holes 311. The condensed liquid coolant can flow into the coolant slide 40 through the drain holes 311, further be directed to the exit 42, and finally flow into the liquid region C1.

FIG. 4 is a perspective view of the condenser module 20 in FIG. 1. The condenser module 20 includes the sealing plate 21, an inlet water box 22, an outlet water box 23, a plurality of first pipes 28, a plurality of second pipes 29 and a connection water box 25. The inlet water box 22 and the outlet water box 23 are fixed to the sealing plate 21. The first pipes 28 are connected between the inlet water box 22 and the connection water box 25, and the second pipes 29 are connected between the outlet water box 23 and the connection water box 25.

In one embodiment, the connection water box 25 is formed with at least one guiding chamfer 251 for directing the condenser module 20 to be installed into the tank 10 through the window 121 of the lateral wall 12 of the tank 10. The guiding chamfer 251 may be a chamfer or a fillet. Moreover, the guiding chamfer 251 is an optional structure, and it may be omitted in other embodiments.

In one embodiment, the connection water box 25 includes a plurality of second guiding structures 252 respectively engaged with the first guiding structures 152. In one embodiment, each of the first guiding structures 152 is a hole, and each of the second guiding structures 252 is a pin inserted into the corresponding hole. However, in other embodiments, the first guiding structure may be a pin, and the second guiding structure may be a hole receiving the pin.

In one embodiment, the condenser module 20 further includes a sealing ring 50 sandwiched between the lateral wall 12 of the tank 10 and the sealing plate 21, and the sealing ring 50 is configured to enhance the sealing performance between the tank 10 and the sealing plate 21. In one embodiment, a groove 211 is formed on the sealing plate 21, and the sealing ring 50 is disposed in the groove 211. In other embodiments, the groove 211 may be formed on an outer surface of the lateral wall 12 of the tank 10.

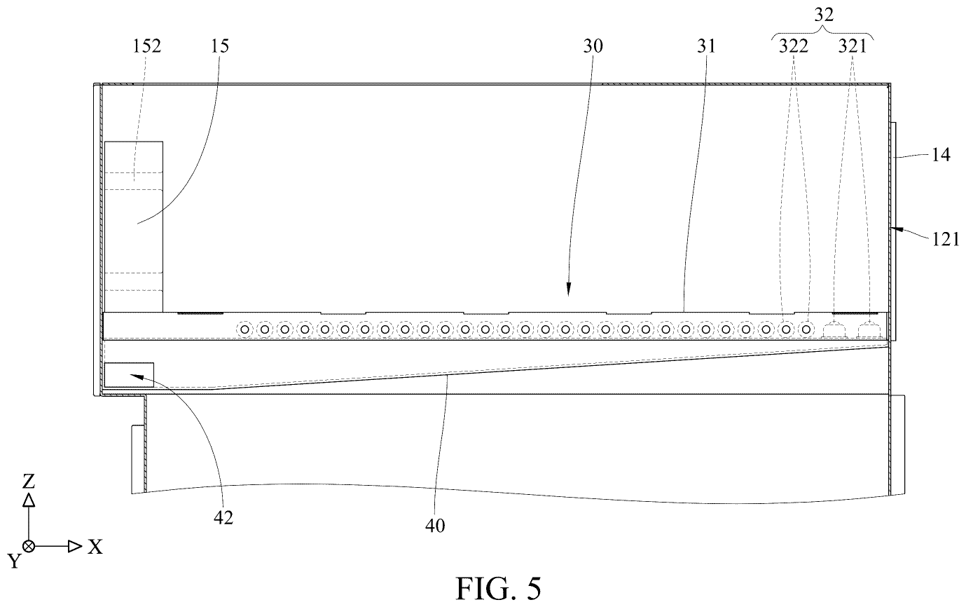

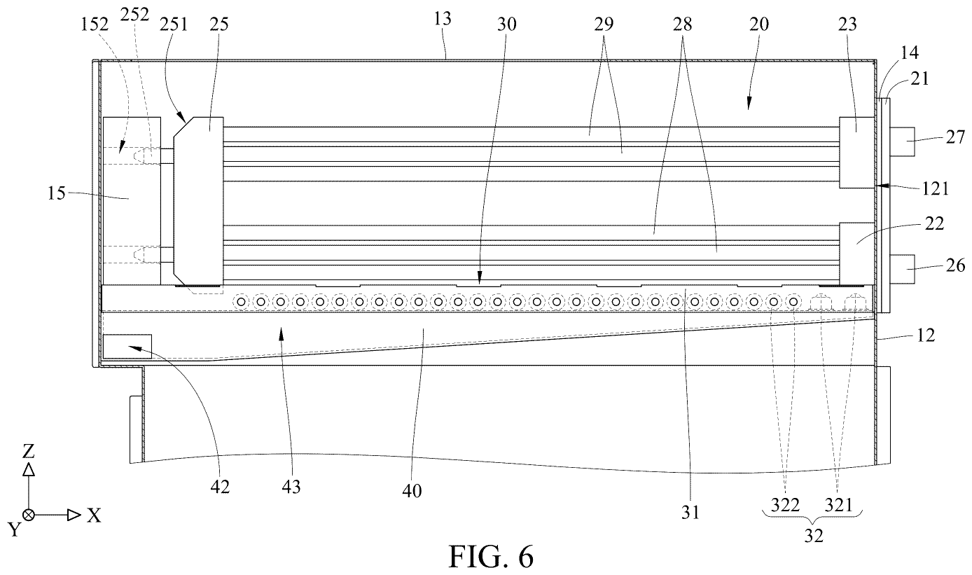

Please refer to FIG. 5 and FIG. 6. FIG. 5 is a side view of the immersion cooling apparatus with the condenser module removed therefrom, and FIG. 6 is a side view of the immersion cooling apparatus with the condenser module disposed therein. As shown in FIG. 5, when the condenser module 20 needs to be maintained or cleaned, the condenser module 20 can be drawn out along the X-axis direction through the window 121. Then, as shown in FIG. 6, the condenser module 20 can be moved to the vicinity of the window 121 by hydraulic lift or crane (not shown in the drawings). The guiding chamfer 251 facilitates the alignment of the condenser module 20 with the window 121. The conveyor module 30 supports the condenser module 20 and transports it into the tank 10. The second guiding structures 252 as well as the first guiding structures 152 engage with each other to position the condenser module 20. Finally, the sealing plate 21 is secured to the frame 14. Therefore, the installation of the condenser module 20 to the tank 10 is completed.

During the operation of the condenser module 20, the low-temperature coolant, such as water supplied from an external cooling water tower (not shown in the drawings), flows from the inlet water box 22 through the first pipes 28, the connection water box 25 and the second pipes 29 in sequence. The high-temperature coolant flows out from the outlet water box 23 after absorbing heat. Since the inlet water box 22 and the first pipes 28 are vertically positioned lower than the outlet water box 23 and the second pipes 29, the low-temperature coolant stays closer to the lower-positioned heat source (i.e., the electronic devices), thereby improving cooling efficiency.

To sum up, the immersion cooling apparatus and the condenser module of the present disclosure have the following advantages: (1) the sealing plate is integrated with the condenser module to seal the tank, thereby making installation and removal convenient; (2) the condenser module can be removed from the tank, thereby making maintenance and cleaning convenient; (3) the inlet and outlet joints are disposed on the sealing plate and located outside of the tank, thereby reducing the risk of damage to the electronic devices due to conductive coolant leakage; (4) a conveyor is disposed below the condenser module, thereby making installation and removal convenient; and (5) a coolant slide is disposed below the condenser module to direct coolant to heat-generating electronic devices, thereby improving cooling efficiency.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A condenser module of an immersion cooling apparatus, comprising:
a sealing plate configured to seal a tank of the immersion cooling apparatus;
an inlet water box fixed to the sealing plate;
an outlet water box fixed to the sealing plate;
a connection water box;
a plurality of first pipes connected between the inlet water box and the connection water box; and
a plurality of second pipes connected between the outlet water box and the connection water box.

2. The condenser module according to claim 1, wherein the connection water box is formed with at least one guiding chamfer.

3. The condenser module according to claim 1, wherein a plurality of first guiding structures are disposed in the tank, the connection water box comprises a plurality of second guiding structures, the plurality of second guiding structures respectively engage with the plurality of first guiding structures.

4. The condenser module according to claim 3, wherein each of the plurality of first guiding structures is a hole, and each of the plurality of second guiding structures is a pin.

5. The condenser module according to claim 1, further comprising a sealing ring, wherein a groove is formed on the sealing plate, and the sealing ring is disposed in the groove.

6. An immersion cooling apparatus, comprising:
a tank comprising a lateral wall having a window; and
the condenser module according to claim 1, wherein the condenser module is disposed in the tank through the window, and the sealing plate of the condenser module is configured to seal the window.

7. The immersion cooling apparatus according to claim 6, further comprising:
a conveyor module disposed in the tank and below the condenser module, wherein the conveyor module is configured to transport the condenser module.

8. The immersion cooling apparatus according to claim 7, wherein the conveyor module comprises:
a tray formed with a plurality of drain holes; and
a plurality of rotating elements disposed on the tray.

9. The immersion cooling apparatus according to claim 8, wherein the plurality of rotating elements comprise at least one of a universal ball or a roller.

10. The immersion cooling apparatus according to claim 8, wherein the plurality of rotating elements comprises:
at least one universal ball proximate to the window; and
at least one roller not proximate to the window.

11. The immersion cooling apparatus according to claim 8, wherein the conveyor module further comprises a plurality of guiding elements, and the plurality of guiding elements are respectively disposed at opposite lateral walls of the tray.

12. The immersion cooling apparatus according to claim 6, further comprising:
a coolant slide disposed in the tank and below the condenser module.

13. The immersion cooling apparatus according to claim 12, wherein an exit is formed on a lateral surface of the coolant slide, and the exit is at a side of the coolant slide away from the window.

14. The immersion cooling apparatus according to claim 13, wherein a height of the lateral surface of the coolant slide gradually increases from the window toward the exit.

15. The immersion cooling apparatus according to claim 6, further comprising:
a frame fixed to an outer surface of the lateral wall and surrounding the window, wherein a plurality of blind holes are formed on the frame, a plurality of through holes are formed on the sealing plate, and a plurality of screws pass through the plurality of through holes and are screwed in the plurality of blind holes.

16. The immersion cooling apparatus according to claim 6, further comprising:
a mounting base disposed on another lateral wall opposite to the lateral wall;
wherein the mounting base has a plurality of first guiding structures, and
when a plurality second guiding structures of the condenser module engage with the plurality of first guiding structures, the condenser module is fixed to the mounting base.
